(19) United States
(12) Patent Application Publication
(10) Pub. No.: US 2024/0379596 A1
(43) Pub. Date: Nov. 14, 2024

(54) CONDUCTIVE PAD ON A THROUGH-SILICON VIA

(71) Applicant: Micron Technology, Inc., Boise, ID (US)

(72) Inventors: Bharat Bhushan, Taichung (TW); Terrence B. McDaniel, Boise, ID (US); Kunal R. Parekh, Boise, ID (US); Bret K. Street, Meridian, ID (US); Akshay N. Singh, Meridian, ID (US)

(21) Appl. No.: 18/660,210

(22) Filed: May 9, 2024

Related U.S. Application Data
(60) Provisional application No. 63/465,514, filed on May 10, 2023.

(51) Int. Cl. H01L 23/00; H01L 21/311; H01L 23/48; H01L 25/065

(52) U.S. Cl. CPC H01L 24/05; H01L 21/31105; H01L 23/481; H01L 24/03; H01L 24/08; H01L 25/0657; H01L 2224/036; H01L 2224/0557; H01L 2224/08145

(57) ABSTRACT

A semiconductor device is provided. The semiconductor device includes a substrate having a front side and a back side opposite the front side. A through via extends entirely through the substrate. The through via includes a protruding portion that extends beyond the back side of the substrate. A layer of silicon carbon nitride is disposed at the back side of the substrate and along sidewalls of the protruding portion of the through via. A layer of oxide is disposed at the back side of the substrate and at least partially surrounding the protruding portion of the through via. A conductive pad is disposed at a coupling surface of the through via and at least partially extending through the layer of oxide. As a result, a reliable and cost-efficient semiconductor device can be assembled.

### CROSS-REFERENCE TO RELATED APPLICATION(S)

The present application claims priority to U.S. Provisional Patent Application No. 63/465,514, filed May 10, 2023, the disclosure of which is incorporated herein by reference in its entirety.

### TECHNICAL FIELD

The present disclosure generally relates to semiconductor device assemblies and more particularly relates to a conductive pad on a through-silicon via (TSV).

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly.

FIG. 2 illustrates a simplified schematic cross-sectional view of a semiconductor device assembly in accordance with an embodiment of the present technology.

FIGS. 3-6 illustrate simplified schematic cross-sectional views of a series of steps for fabricating semiconductor device assemblies in accordance with an embodiment of the present technology.

FIG. 7 illustrates a schematic view of a system that includes a semiconductor device assembly configured in accordance with an embodiment of the present technology.

FIG. 8 illustrates a method of fabricating a semiconductor device assembly in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device. This development, however, may not be sustainable due to various challenges that arise from designing semiconductor devices with high circuit density. Thus, additional techniques may be required to continue the growth in capability of semiconductor devices.

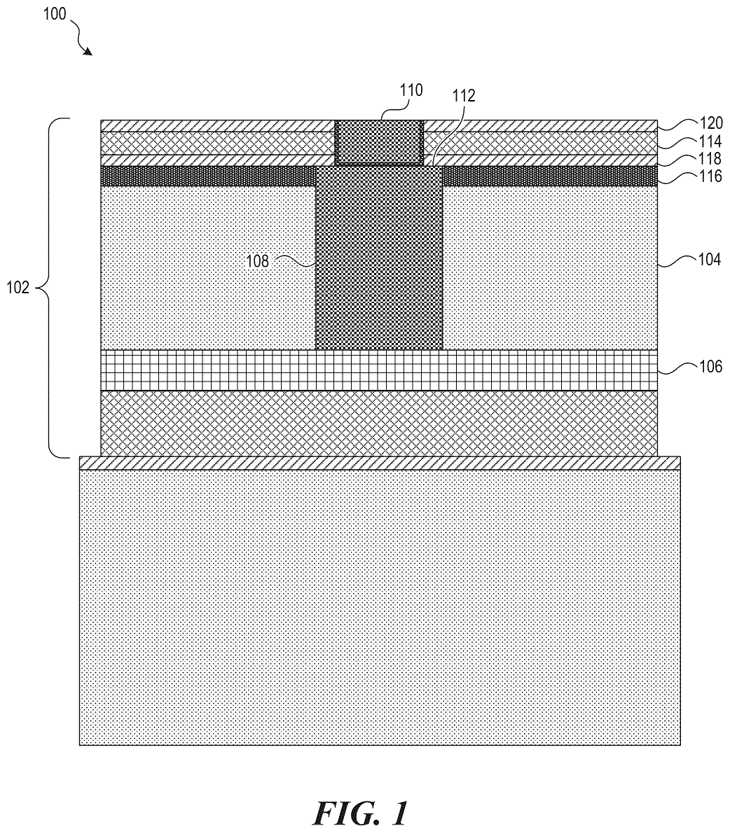

One such technique is to implement multiple circuit components within a single package. For example, stacked semiconductor devices enable multiple semiconductor dies to be stacked on top of one another to increase the number of circuit elements within a package without increasing its footprint. In some cases, individual semiconductor dies may be stacked on top of one another to produce a vertical stack of semiconductor dies. The semiconductor dies can include through-silicon vias (TSVs) that extend between a front side (e.g., active side at which circuitry is disposed) and a back side opposite the front side. Contact pads may be disposed at the back side of the semiconductor dies in contact with an exposed portion of the TSVs to enable an additional semiconductor die to be electrically coupled thereat. Various techniques exist for disposing contact pads at TSVs, however, some of these techniques may be overly time-consuming or produce semiconductor devices with reliability or cost concerns. An example semiconductor device is shown in FIG. 1.

FIG. 1 illustrates a semiconductor device assembly 100 that includes a semiconductor die 102. The semiconductor die 102 may be assembled onto a carrier wafer to enable the semiconductor die 102 to withstand processing. The semiconductor die 102 includes a substrate 104 (e.g., silicon substrate, organic substrate, printed circuit board (PCB) core, etc.) having a metallization layer 106 (e.g., with connective circuitry, such as traces, lines, and vias) at a front side. A TSV 108 extends entirely through the substrate 104 from the front side to a back side opposite the front side. A contact pad 110 may be disposed on a coupling surface 112 of the TSV 108 exposed at the back side of the substrate 104. The contact pad 110 may be disposed within a layer of oxide 114 (e.g., high-temperature silicon oxide deposited at a temperature above 300, 400, 500, or 700 degrees Celsius).

Various techniques may be used to dispose the contact pad 110 of the TSV 108. For example, initially, the TSV 108 may protrude beyond the back side of the substrate 104 (e.g., by more than three microns). A layer of silicon nitride 116 (e.g., low-temperature silicon nitride deposited at a temperature less than 200, 300, or 400 degrees Celsius) may be disposed at the back side of the substrate, along sidewalls of the TSV 108, and over top of the TSV 108. In some cases, the layer of silicon nitride is disposed with a thickness greater than one micron. A layer of oxide (not shown), such as a low-temperature oxide, may then be deposited at the back side of the semiconductor die 102 over the layer of silicon nitride 116. The layer of oxide may be disposed with a thickness of around 0.5 microns (e.g., within. 1 microns, within 0.2 microns, etc.). Material may then be removed from the backside of the semiconductor die 102 through chemical-mechanical planarization (CMP) to expose the TSV 108. For instance, the layer of oxide may be entirely removed and the layer of silicon nitride 116 may be thinned to around one micron (e.g., within 0.1 microns, within 0.2 microns, within 0.5 microns, etc.). In this way, a back side of the semiconductor die 102 may correspond to a planarized layer of silicon nitride 116 with the coupling surface 112 of the TSV 108 exposed.

A layer of silicon carbon nitride 118 (e.g., a high-temperature silicon carbon nitride) can then be disposed at the layer of silicon nitride 116 and over the coupling surface 112 of the TSV 108. The layer of oxide 114 can be disposed at the back side of the semiconductor die 102 over the layer of silicon carbon nitride 118. An additional layer of silicon carbon nitride 120 (e.g., high-temperature silicon carbon nitride) can then be disposed over the layer of oxide 114. The layer of silicon carbon nitride 118, the layer of oxide 114, and the layer of silicon carbon nitride 120 may be etched (e.g., dry etched) to expose the coupling surface 112 of the TSV 108. The contact pad 110 may then be disposed in the opening at the coupling surface 112 such that the contact pad 110 is exposed at the back side of the semiconductor die 102. In doing so, additional semiconductor dies may be stacked onto the semiconductor die 102 and electrically coupled at the contact pad 110.

Using these techniques to dispose a contact pad on a TSV may be suboptimal for any number of reasons. As discussed above, the process may involve multiple deposition steps to dispose various layers at the back side of the semiconductor die 102 (e.g., the layer of silicon nitride 116 or the layer of oxide that is later removed). As a result, implementation of the design process may require a large amount of time and have a large material cost. Moreover, the coupling surface 112 of the TSV 108 may be exposed through CMP, which can result in smearing of the conductive material within the TSV 108 across the back side of the semiconductor die 102 or fracture of the semiconductor die 102. In this way, the use of CMP may reduce the reliability of the semiconductor die 102 or reduce yield. In yet another aspect, the use of CMP in areas that do and do not include the TSV 108 can create topography (e.g., differences in height of up to 200 nanometers) on the back surface of the semiconductor die 102. The topography may result from a tendency of an area that includes the TSV 108 to resist CMP more than an area that does not include the TSV 108. In some cases, this topography can create vulnerabilities in the semiconductor die 102 or make it difficult to stack additional semiconductor dies on the semiconductor die 102. In aspects, the topography can reduce the reliability of metal-metal bonding at the TSV 108 (e.g., due to DC resistance yield). Thus, designing semiconductor devices using these techniques may create semiconductor devices with reliability concerns or require undue cost or manufacture time.

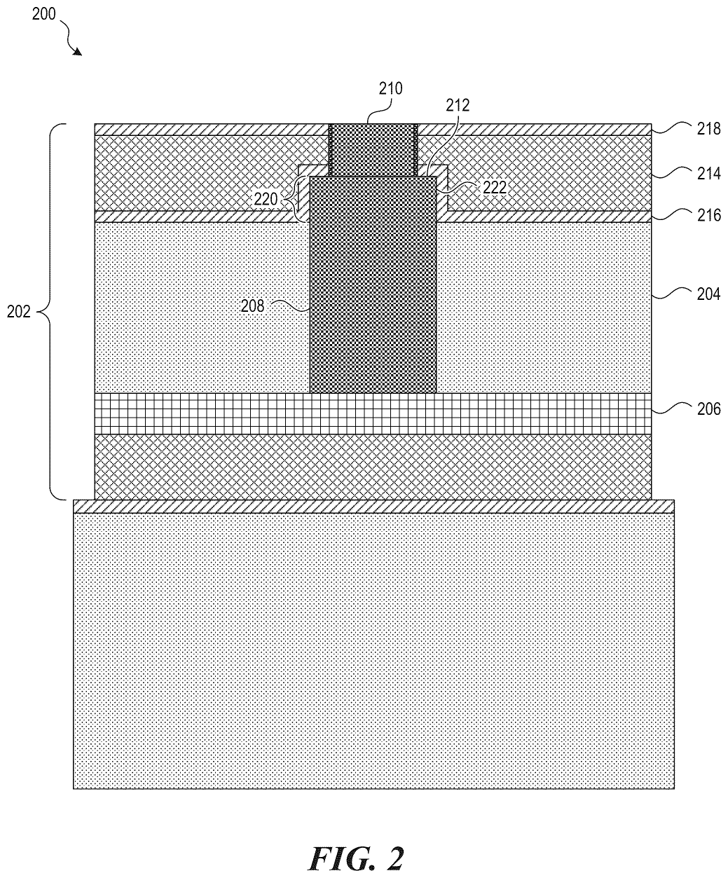

To address these drawbacks and others, various embodiments of the present technology provide semiconductor device assemblies that include a contact pad disposed at a TSV. The semiconductor device includes a substrate having a front side and a back side opposite the front side. A through via extends entirely through the substrate. The through via includes a protruding portion that extends beyond the back side of the substrate. A layer of silicon carbon nitride is disposed at the back side of the substrate and along sidewalls of the protruding portion of the through via. A layer of oxide is disposed at the back side of the substrate and at least partially surrounding the protruding portion of the through via. A conductive pad is disposed at a coupling surface of the through via and at least partially extending through the layer of oxide. As a result, a reliable and cost-efficient semiconductor device can be assembled, an example of which is shown in FIG. 2.

FIG. 2 illustrates a semiconductor device assembly 200 that includes a semiconductor die 202. The semiconductor die 202 may be assembled onto a carrier wafer to enable the semiconductor die 202 to withstand processing. The semiconductor die 202 includes a substrate 204 having a metallization layer 206 (e.g., with connective circuitry, such as traces, lines, and vias) at a front side. A TSV 208 extends entirely through the substrate 204 from the front side to a back side opposite the front side. A contact pad 210 may be disposed on a coupling surface 212 of the TSV 208. The contact pad 210 may be disposed within a layer of oxide 214 (e.g., a high-temperature silicon oxide) and exposed at the back side of the semiconductor die 202. A layer of silicon carbon nitride 216 (e.g., high-temperature silicon carbon nitride) may be disposed at the back side of the substrate 204, and a layer of silicon carbon nitride 218 may be disposed at the layer of oxide 214 opposite the layer of silicon carbon nitride 218.

In contrast to the semiconductor device assembly 100 illustrated in FIG. 1, the TSV 208 may have a protruded portion 220 that extends beyond the back side of the substrate 204. For example, the protruded portion 220 may extend beyond the back side of the substrate 204 by more than 1 micron, more than 2 microns, more than 3 microns, more than 4 microns, or more than 5 microns. The layer of silicon carbon nitride 216 may be disposed at the back side of the substrate 204, extending along sidewalls 222 of protruding portion 220 of the TSV 208 and extending over a portion of the coupling surface 212. In this way, the layer of silicon carbon nitride 216 may follow the shape of the protruding portion 220 of the TSV 208. In aspects, the layer of silicon carbon nitride 216 may be around 0.15 microns thick (e.g., within 0.01 microns, within 0.05 microns, within 0.1 microns, etc.). As illustrated, the layer of silicon carbon nitride 216 may be directly in contact with the substrate 204 (e.g., at the back side). For example, the layer of silicon carbon nitride 216 and the substrate 204 may not be separated by another material (e.g., the layer of silicon nitride 116 of FIG. 1).

The contact pad 210 may be disposed at the back side of the semiconductor die 202 on a coupling surface 212 of the TSV 208. In aspects, the contact pad 210 may be smaller than the coupling surface 212 of the TSV 208 such that the contact pad 210 contacts only a portion of the coupling surface 212. For example, a cross-sectional area of the contact pad 210 in a plane coplanar with the coupling surface 212 is smaller than the area of the coupling surface 212. A surface of the contact pad 210 may be disposed at the back side of the semiconductor die 202 to enable an additional semiconductor die to be stacked on the semiconductor die 202 and electrically coupled with the semiconductor die 202 at the contact pad 210.

Although illustrated and described as a semiconductor die, the semiconductor die 202 could be replaced with a wafer (e.g., semiconductor wafer) implementing multiple semiconductor dies. For example, the substrate 204 could be replaced with a wafer-level or panel-level substrate used to implement multiple semiconductor dies. Moreover, although described as a TSV, the TSV 208 may generally refer to a through-substrate via. As such, the TSV 208 may be implemented through a non-silicon substrate, for example, an organic substrate or other semiconductor substrate. In yet another aspect, although described with reference to particular materials, other materials may be used to form the various layers of the semiconductor die 202. In this way, the layer of oxide 214, the layer of silicon carbon nitride 216, or the layer of silicon carbon nitride 218 may instead include any other material, for example, a different dielectric material (e.g., silicon oxide, silicon nitride, silicon carbide, silicon carbon nitride, or the like).

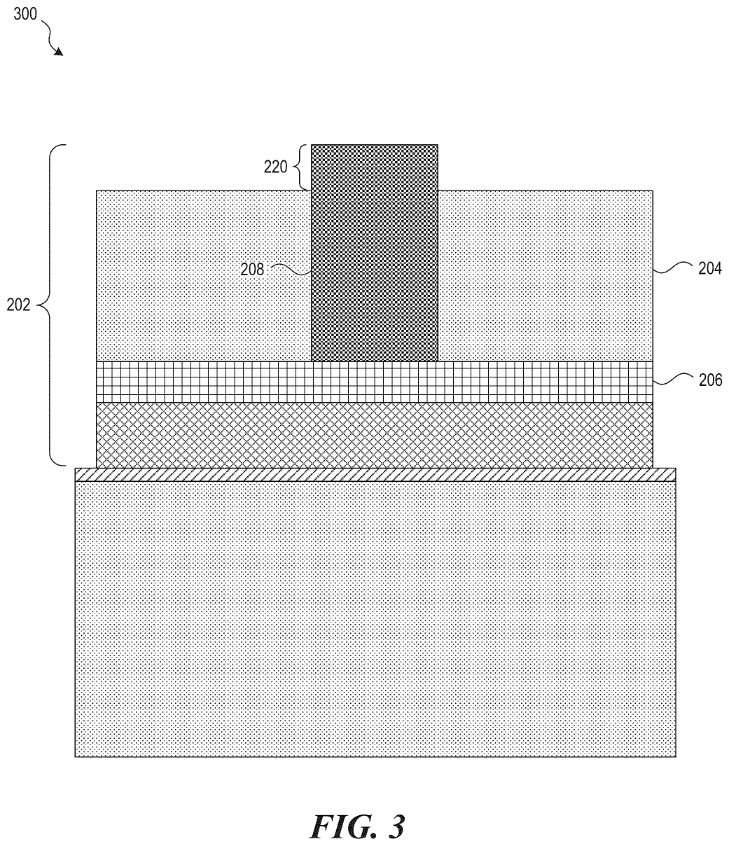

This disclosure now turns to a series of steps for fabricating semiconductor device assemblies in accordance with embodiments of the present technology. Specifically, FIGS. 3-6 illustrate simplified schematic cross-sectional views of a series of steps for fabricating semiconductor device assemblies in accordance with an embodiment of the present technology. The steps are illustrated with respect to specific embodiments for ease of description. However, these steps could be performed to fabricate semiconductor device assemblies in accordance with other embodiments.

Beginning with FIG. 3 at stage 300, a simplified schematic cross-sectional view of a semiconductor device assembly is illustrated. The semiconductor device assembly includes the semiconductor die 202 assembled onto a carrier substrate. The semiconductor die 202 can be adhered (e.g., through an adhesive or a dielectric material) to the carrier substrate in a face-down arrangement such that a front side of the semiconductor die 202 faces toward the carrier substrate. The semiconductor die 202 may be implemented at a substrate 204. A metallization layer 206 that includes traces, lines, vias, and other connective structures may be disposed at the front side of the semiconductor die 202. The TSV 208 extends entirely through the substrate 204 from the metallization layer 206. A protruded portion 220 of the TSV 208 extends beyond the back side of the substrate 204. For example, the protruded portion 220 of the TSV 208 may extend past the back side of the substrate 204 by an amount larger than 1 micron, larger than 2 microns, larger than 3 microns, larger than 4 microns, larger than 5 microns, etc.

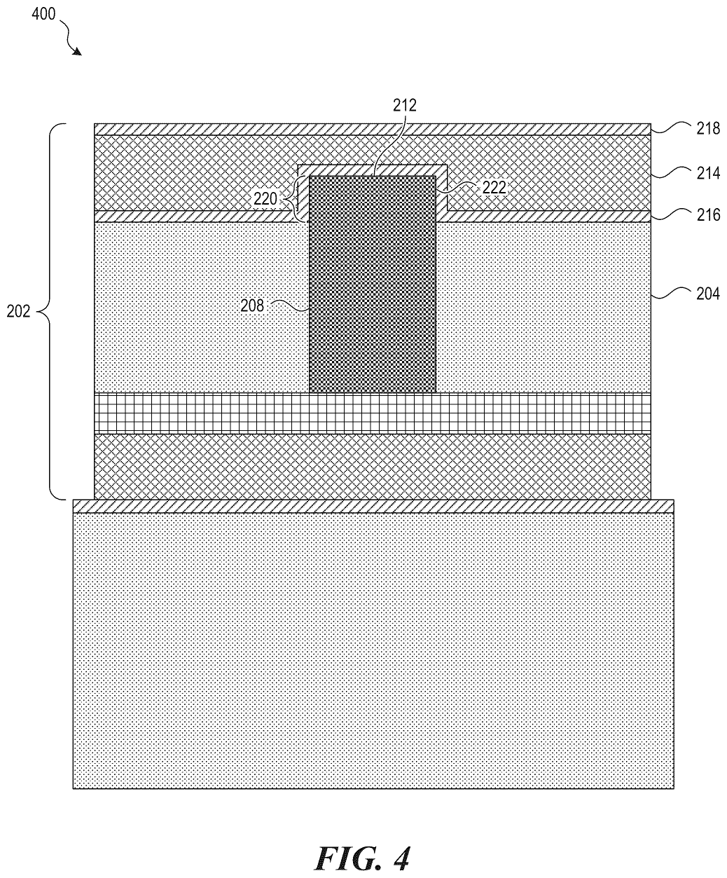

FIG. 4 illustrates a simplified schematic cross-sectional view of stage 400, where passivation material is disposed at the back side of the substrate 204 around a protruded portion 220 of the TSV 208. A coupling surface 212 of the TSV 208 may be exposed at a distal portion of the protruding portion 220 of the TSV 208. In aspects, the protruded portion 220 is not planarized down to be roughly coplanar with the back side of the substrate 204 (e.g., within 0.5 microns, within 1 micron, within 2 microns, within 5 microns, etc.). Accordingly, the back side of the substrate 204 can have a topography less than 200 nanometers, less than 100 nanometers, less than 50 nanometers. Instead of planarizing down to the backside of the substrate 204, a layer of silicon carbon nitride 216 may be deposited at the back side of the substrate 204 (e.g., in direct contact with the back side of the substrate 204) and around the protruding portion 220 of the TSV 208. For instance, the layer of silicon carbon nitride 216 may be disposed at the back side of the substrate 204, along sidewalls 222 of the protruded portion 220, and over the coupling surface 212. The layer of silicon carbon nitride 216 may include a high-temperature silicon carbon nitride deposited at a temperature above 300, 400, 500, or 700 degrees Celsius. The layer of silicon carbon nitride 216 may be disposed with a thickness of around. 15 microns (e.g., within 0.01 microns, within 0.05 microns, within 0.1 microns, etc.).

A layer of oxide 214 (e.g., high-temperature silicon oxide) may be disposed at least partially around the protruded portion 220. For example, the layer of oxide 214 can be deposited such that the layer of oxide 214 extends more than 1 micron above the protruded portion 220. The layer of oxide 214 may be disposed at the layer of silicon carbon nitride 216 such that the layer of silicon carbon nitride 216 separates the substrate 204 and the TSV 208 from the layer of oxide 214. An additional layer of silicon carbon nitride 218 may then be disposed at the layer of oxide 214 opposite the layer of silicon carbon nitride 216 (e.g., opposite the substrate 204).

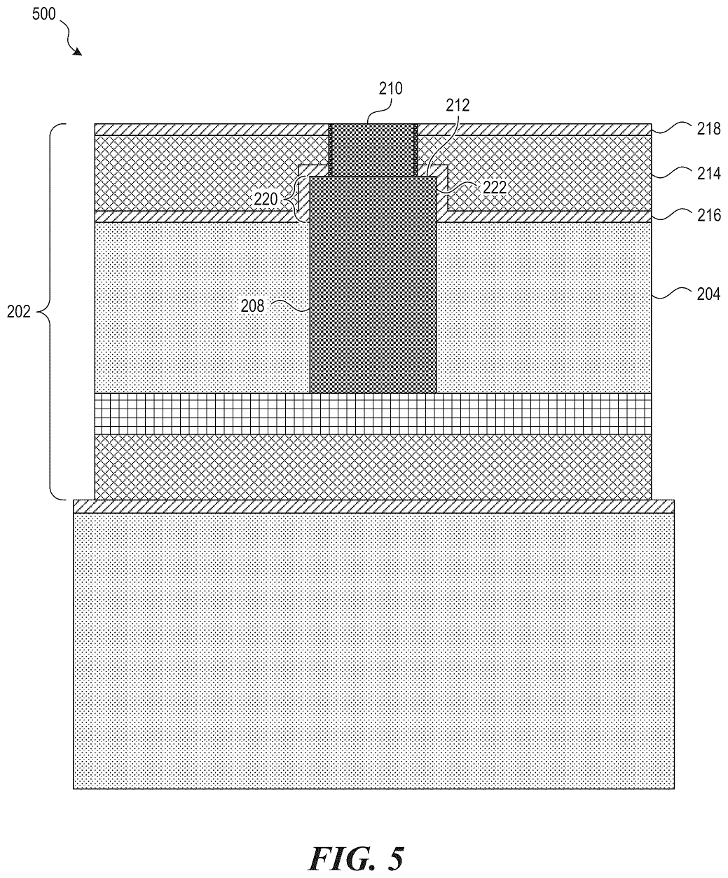

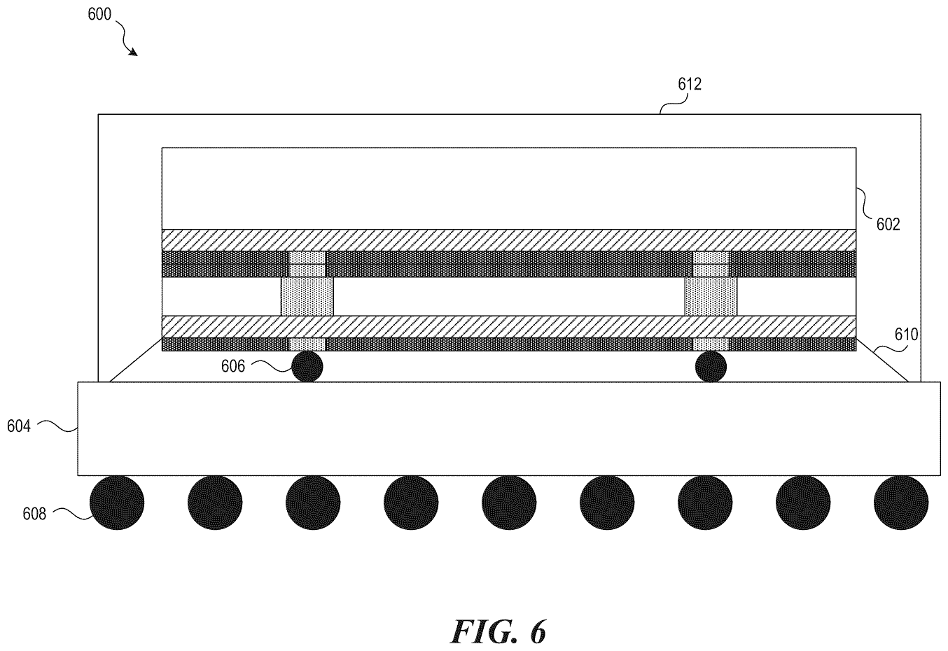

FIG. 5 illustrates a simplified schematic cross-sectional view of a stage 500, where a contact pad 210 is disposed at the coupling surface 212 of the TSV 208 such that the contact pad 210 is electrically coupled to the TSV 208. Portions of the layer of oxide 214, the layer of silicon carbon nitride 216 and the layer of silicon carbon nitride 218 may be removed to expose the coupling surface 212 of the TSV 208. For example, the material may be removed through etching. Then, conductive material may be disposed in the opening to implement the contact pad 210. The contact pad 210 may be smaller than the coupling surface 212 of the TSV 208. In this way, the layer of silicon carbon nitride 216 may still cover a portion of the coupling surface 212 of the TSV 208. In aspects, CMP is not used to expose the coupling surface 212 of the TSV 208. As a result, the risk of contamination from the TSV 208 or fracture of the semiconductor die 202 may be eliminated. In yet another aspect, not planarizing the TSV 208 down to the substrate may remove steps to deposit passivation material at the substrate 204 (e.g., the low-temperature layer of oxide that is removed through CMP during fabrication of the semiconductor device assembly described with respect to FIG. 1) or planarize the TSV 208, thereby simplifying the manufacturing process and reducing the total cost to produce the semiconductor device assembly. An additional semiconductor die may then be stacked onto the semiconductor die 202, and the stacked semiconductor dies may be packaged as a packaged semiconductor device, an example of which is shown in FIG. 6.

FIG. 6 illustrates a simplified schematic cross-sectional view of a semiconductor device assembly at stage 600. The semiconductor device assembly 600 includes stacked semiconductor dies 602. One or more of the stacked semiconductor dies 602 may include TSVs with contact pads disposed thereat. In doing so, interconnects (e.g., metal-metal interconnects) electrically coupling the semiconductor dies 602 may be formed between respective contact pads on respective dies of the stack semiconductor dies 602. The stacked semiconductor dies 602 may be assembled onto a package-level substrate 604 through conductive structures 606 (e.g., conductive pillars, solder joints, etc.). For example, contact pads at a base die of the stacked semiconductor dies 602 may electrically couple with contact pads (not shown) at an upper surface of the package-level substrate 604 through the conductive structures 606. The package-level substrate 604 can include internal circuitry (traces, lines, vias, and other connective structures) that connects the contact pads at the upper surface to contact pads (not shown) at the lower surface. Conductive structures 608 may be disposed at the contact pads at the lower surface to provide external connectivity (e.g., power, ground, input/output (I/O) signaling, or the like) to the stacked semiconductor dies 602. An underfill material 610 (e.g., capillary underfill) may be disposed around the conductive structures 606 to electrically insulate these structures and mechanically support the semiconductor device assembly 600. An encapsulant 612 (e.g., mold resin) may be disposed at least partially around the stacked semiconductor dies 602 and the package-level substrate 604 to protect the semiconductor device assembly 600 and prevent electrical contact therewith.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with a vertical stack of semiconductor dies (e.g., in accordance with the high bandwidth memory (HBM protocol), multiple stacks of semiconductor dies, a plurality of semiconductor dies, a single semiconductor die, mutatis mutandis.

In accordance with one aspect of the present disclosure, the semiconductor devices illustrated in the assemblies of FIGS. 1-6 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

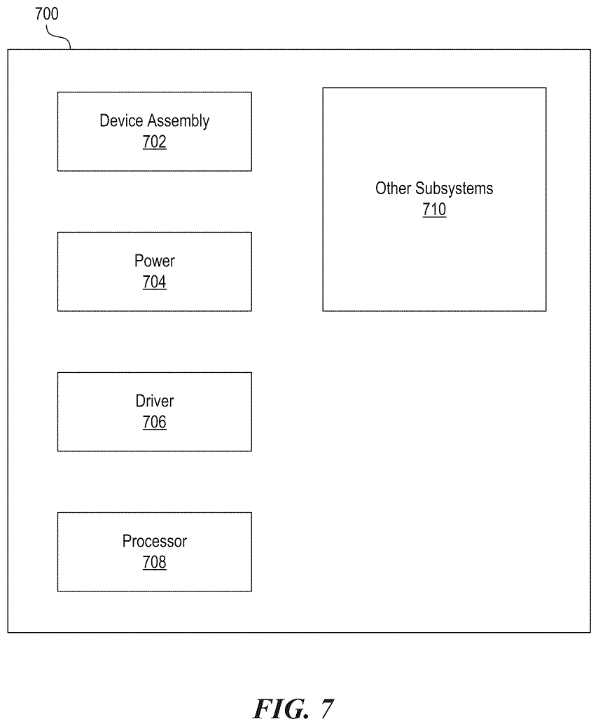

Any one of the semiconductor devices and semiconductor device assemblies described above with reference to FIGS. 1-6 can be incorporated into any of a myriad of larger and/or more complex systems, a representative example of which is system 700 shown schematically in FIG. 7. The system 700 can include a semiconductor device assembly 702 (e.g., a discrete semiconductor device), a power source 704, a driver 706, a processor 708, and/or other subsystems or components 710. The semiconductor device assembly 702 can include features generally similar to those of the semiconductor device assemblies described above with reference to FIGS. 1-6. The resulting system 700 can perform any of a wide variety of functions, such as memory storage, data processing, and/or other suitable functions. Accordingly, representative systems 700 can include, without limitation, handheld devices (e.g., mobile phones, tablets, digital readers, and digital audio players), computers, vehicles, appliances, and other products. Components of the system 700 may be housed in a single unit or distributed over multiple, interconnected units (e.g., through a communications network). The components of the system 700 can also include remote devices and any of a wide variety of computer-readable media.

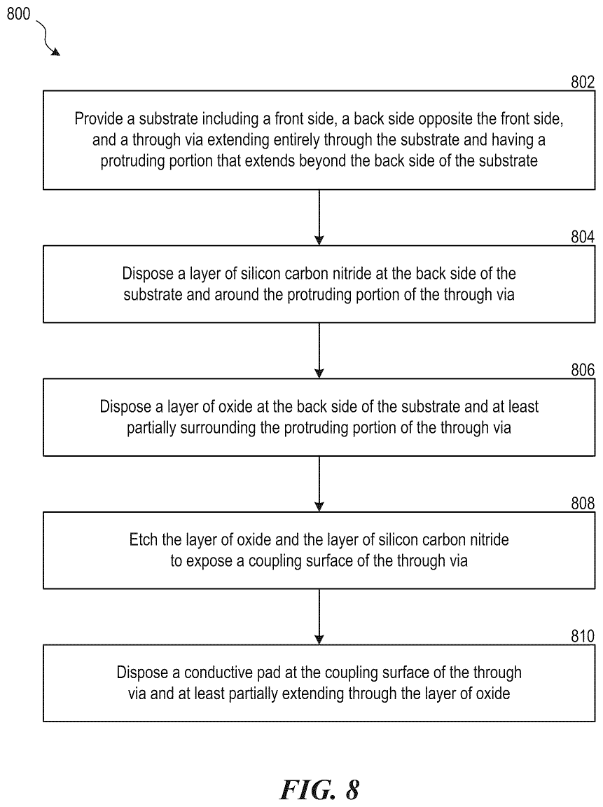

FIG. 8 illustrates an example method 800 for fabricating a semiconductor device assembly in accordance with an embodiment of the present technology. Although illustrated in a particular configuration, one or more operations of the method 800 may be omitted, repeated, or reorganized. Additionally, the method 800 may include other operations not illustrated in FIG. 8, for example, operations detailed in one or more other methods described herein.

At 802, a substrate is provided. The substrate may include a front side, a back side opposite the front side, and a through via extending entirely through the substrate and having a protruding portion that extends beyond the back side of the substrate. At 804, a layer of silicon carbon nitride is disposed at the back side of the substrate and around the protruding portion of the through via. At 806, a layer of oxide is disposed at the back side of the substrate and at least partially surrounding the protruding portion of the through via. At 808, the layer of oxide and the layer of silicon carbon nitride are etched to expose a coupling surface of the through via. At 810, a conductive pad is disposed at the coupling surface of the through via and at least partially extending through the layer of oxide.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3DI) applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate by ion-implantation or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a substrate having a front side and a back side opposite the front side;
a through via extending entirely through the substrate and having a protruding portion that extends beyond the back side of the substrate;
a layer of silicon carbon nitride disposed at the back side of the substrate and extending along sidewalls of the protruding portion of the through via;
a layer of oxide disposed at the back side of the substrate and at least partially surrounding the protruding portion of the through via; and
a conductive pad disposed at a coupling surface of the through via and at least partially extending through the layer of oxide.

2. The semiconductor device of claim 1, wherein the layer of silicon carbon nitride directly contacts the back side of the substrate.

3. The semiconductor device of claim 1, wherein the layer of silicon carbon nitride extends over a portion of the coupling surface of the through via.

4. The semiconductor device of claim 1, further comprising an additional layer of silicon carbon nitride disposed at the layer of oxide opposite the layer of silicon carbon nitride.

5. The semiconductor device of claim 1, wherein a surface area of the conductive pad in a plane coplanar to the coupling surface of the through via is smaller than a surface area of the coupling surface of the through via.

6. The semiconductor device of claim 1, wherein the back side of the substrate has a topography less than 200 nanometers.

7. The semiconductor device of claim 1, wherein the layer of oxide comprises tetraethyl orthosilicate, spin-on-dielectric, or spin-on-glass.

8. A method for fabricating a semiconductor device, comprising:
providing a substrate including a front side, a back side opposite the front side, and a through via extending entirely through the substrate and having a protruding portion that extends beyond the back side of the substrate;
disposing a layer of silicon carbon nitride at the back side of the substrate and around the protruding portion of the through via;
disposing a layer of oxide at the back side of the substrate and at least partially surrounding the protruding portion of the through via;
etching the layer of oxide and the layer of silicon carbon nitride to expose a coupling surface of the through via; and
disposing a conductive pad at the coupling surface of the through via and at least partially extending through the layer of oxide.

9. The method of claim 8, further comprising disposing the layer of silicon carbon nitride in direct contact with the back side of the substrate.

10. The method of claim 8, further comprising disposing the layer of silicon carbon nitride at a temperature above 700 degrees Celsius.

11. The method of claim 8, further comprising etching the layer of oxide and the layer of silicon carbon nitride to expose the coupling surface of the through via such that a portion of the layer of silicon carbon nitride extends over a portion of the coupling surface at which the conductive pad is not disposed.

12. The method of claim 8, further comprising disposing an additional layer of silicon carbon nitride at the layer of oxide opposite the layer of silicon carbon nitride.

13. The method of claim 8, further comprising disposing the layer of oxide through flowable chemical vapor deposition, fluid vapor deposition, or spin coating.

14. A semiconductor device, comprising:
a substrate having a front side and a back side opposite the front side;
a through via extending entirely through the substrate and having a protruding portion that extends beyond the back side of the substrate;
a layer of silicon carbon nitride directly contacting the back side of the substrate;
a layer of oxide disposed at the back side of the substrate and over the protruding portion of the through via; and
a conductive pad disposed at a coupling surface of the through via and at least partially extending through the layer of oxide.

15. The semiconductor device of claim 14, wherein the layer of silicon carbon nitride extends along sidewalls of the protruding portion of the through via.

16. The semiconductor device of claim 14, wherein the layer of silicon carbon nitride extends over a portion of the coupling surface of the through via.

17. The semiconductor device of claim 14, further comprising an additional layer of silicon carbon nitride disposed at the layer of oxide opposite the layer of silicon carbon nitride.

18. The semiconductor device of claim 14, wherein a cross-sectional area of the conductive pad in a plane coplanar to the coupling surface of the through via is smaller than an area of the coupling surface of the through via.

19. The semiconductor device of claim 14, further comprising:
a semiconductor die that includes the substrate and the contact pads; and
an additional semiconductor die that includes additional contact pads,
wherein the semiconductor die and the additional semiconductor die couple at the contact pads and the additional contact pads to implement a stack of semiconductor dies in accordance with the high-bandwidth memory protocol.

20. The semiconductor device of claim 14, further comprising:
a logic die;
a semiconductor die that includes the substrate and the contact pads and is coupled with the logic die at a first lateral location;
an additional semiconductor die that includes additional contact pads,
wherein the semiconductor die and the additional semiconductor die couple at the contact pads and the additional contact pads to implement a first stack of semiconductor dies; and
a second stack of semiconductor dies coupled with the logic die at a second lateral location.
